(19) United States
(12) Patent Application Publication
(10) Pub. No.: US 2009/0142490 A1
(43) Pub. Date: Jun. 4, 2009

(54) FILM FORMING METHOD AND FILM FORMING APPARATUS

(75) Inventor: Yohei Ishida, Honjo-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 12/326,651

(22) Filed: Dec. 2, 2008

(30) Foreign Application Priority Data
Dec. 4, 2007 (JP) 2007-313901

(51) Int. Cl. C23C 16/00

(52) U.S. Cl. 427/248.1

(57) ABSTRACT

In a method of forming on a substrate a film of a substance by depositing the substance vaporized from an evaporation source on the substrate in an oblique direction, a deposition rate of the substance is changed depending on a position on the substrate so that the deposition rate of the substance is higher at the position in which the deposition angle is larger.

### FIELD OF THE INVENTION AND RELATED ART

The present invention relates to a film forming method and a film forming apparatus, particularly a method for forming a liquid crystal alignment film of an inorganic material and a film forming apparatus therefor.

A liquid crystal display device used for a PC monitor, a thin-shaped television, a projector, and the like has undergone variety of evolution depending on its intended purpose in recent years. The liquid crystal display device basically has such a structure that a liquid crystal composition is held between a pair of substrates on which electrodes, and alignment films are formed although a wide variety of a liquid crystal, the alignment film, the electrodes, the substrate, and the like used therein are employed depending on uses. The alignment film has a function of regulating alignment of liquid crystal molecules in a certain direction. The alignment of the liquid crystal molecules in one direction is essential for the liquid crystal display device to have a switching function and therefore a characteristic of the alignment film largely affects a display characteristic of the liquid crystal display device.

As the alignment film, an organic alignment film represented by a polyimide film has been used widely. However, a liquid crystal display device, used in an environment of irradiation with strong light, such as a projector, is deteriorated by light in a short period of time. For this reason, there is no organic alignment film subjected to practical use. Therefore, a light-resistance alignment film of an inorganic substance having high light resistance is desired.

The inorganic alignment film is generally formed by using deposition (evaporation) which is called oblique deposition. This is a method of forming an inorganic alignment film on a substrate, wherein a vacuum an evaporation source is heated by resistance heating or electron beam irradiation to vaporize an oxide on a boat or in a crucible so that a deposition substance is deposited on the substrate in an oblique direction. An angle formed between a line segment connecting the substrate with the evaporation source and a normal to the substrate is referred to as a “deposition angle”. As the material for the inorganic alignment film, an oxide is generally used and particularly, silicon oxide (SiOₓ; x=1 to 2) is frequently used. By the oblique deposition, on the substrate a film having a minute columnar structure is formed with respect to an oblique direction. The surface of the oblique deposition film having the columnar structure has a shape anisotropy correspondingly to the deposition angle and the deposition direction, so that the liquid crystal is aligned in one direction.

The inorganic alignment film formed by the oblique deposition is different in state of liquid crystal alignment depending on the deposition angle. An inclination angle of the liquid crystal molecules with respect to a surface of the alignment film, i.e., a pretilt angle can be controlled by the deposition angle. The pretilt angle is a parameter largely affecting a display quality. Particularly, in order to suppress a disclination line leading to a lowering in contrast, the liquid crystal device may desirably have the pretilt angle to some extent. A correlation between the deposition angle and the pretilt angle has been confirmed. However, with an increasing deposition angle, a change in pretilt angle with respect to the deposition angle becomes abrupt, so that a distribution of the pretilt angle is caused to occur depending on the change in deposition angle in an in-plane surface of the substrate. This is a major problem particularly when the oblique deposition is performed with respect to a large-area substrate. The change in deposition angle in the in-plane surface of the substrate can be decreased by increasing a deposition distance but the increase in deposition distance is required with an increasing substrate area, thus leading to a large-sized apparatus.

Japanese Laid-Open Patent Application (JP-A) 2003-129225 has proposed a method of controlling a flow rate of a deposition substance passing through a plurality of slits different in opening areas.

As described above, the pretilt angle directly affects a characteristic of the liquid crystal device, so that a method capable of further uniformizing the deposition angle and a thickness of the deposition film with accuracy and capable of easily meeting the change in size of the substrate has been desired.

### SUMMARY OF THE INVENTION

The present invention has been accomplished in view of the above-described problem.

A principal object of the present invention is to provide a method of forming an alignment film providing a uniform deposition angle without increasing a deposition distance even in the case of using a large-area substrate having a diameter of 20 cm or more.

According to an aspect of the present invention, there is provided a method of forming on a substrate a film of a substance by depositing the substance vaporized from an evaporation source on the substrate in an oblique direction, the method comprising a step of:

changing a deposition rate of the substance depending on a position on the substrate so that the deposition rate of the substance is higher at the position in which the deposition angle is larger.

According to the present invention, it is possible to easily form an alignment film, with a highly yield, such that a desired pretilt angle is uniformly exhibited over the entire surface of a deposition substrate even in the case where a relative large-area substrate is used and a deposition distance is relatively small. The

By using the film forming method of the present invention, compared with a conventional oblique deposition film production apparatus, the deposition distance can be decreased to reduce the size of a film forming apparatus and a products cost.

Further, according to the present invention, by using the film forming method and the film forming apparatus, it is possible to provide a liquid crystal display device, set to provide a desired pretilt angle, capable of effecting high-quality display and direct-view type and projection type display apparatus using the liquid crystal display device.

The present invention is applicable to a liquid crystal display device using an inorganic alignment film formed by the oblique deposition. Further, the present invention is applicable to display apparatuses using the liquid crystal display device such as a projection display apparatus such as a projector or the like, a liquid crystal monitor, a liquid crystal television, and the like.

These and other objects, features and advantages of the present invention will become more apparent upon a consideration of the following description of the preferred embodiments of the present invention taken in conjunction with the accompanying drawings.

### BRIEF DESCRIPTION OF THE DRAWINGS

FIG. 1 is a schematic view showing an embodiment of a constitution of an apparatus when an alignment film is prepared by oblique deposition.

FIG. 2 is a schematic view showing an embodiment of an apparatus used in an alignment film forming method of the present invention.

FIGS. 3(a) to 3(c) are schematic views showing an embodiment of the alignment film forming method of the present invention.

FIGS. 4(a) to 4(c) are schematic views each showing a film forming area for illustrating the alignment film forming method of the present invention.

FIGS. 5(a) to 5(c) are schematic views showing another embodiment of the alignment film forming method of the present invention.

FIG. 6 is a schematic view for illustrating a pretilt angle in a liquid crystal display device.

FIG. 7 is a schematic view for illustrating measuring points in Example 2 of the present invention.

FIG. 8 is a graph showing a relationship between a film forming speed and a pretilt angle in the present invention.

### DESCRIPTION OF THE PREFERRED EMBODIMENTS

Hereinbelow, the present invention will be described in detail. The present invention is a method of forming a film on a substrate by oblique deposition, particularly a film forming method of a liquid crystal alignment film using an inorganic substance as a film forming material.

### <Alignment Film Forming Method>

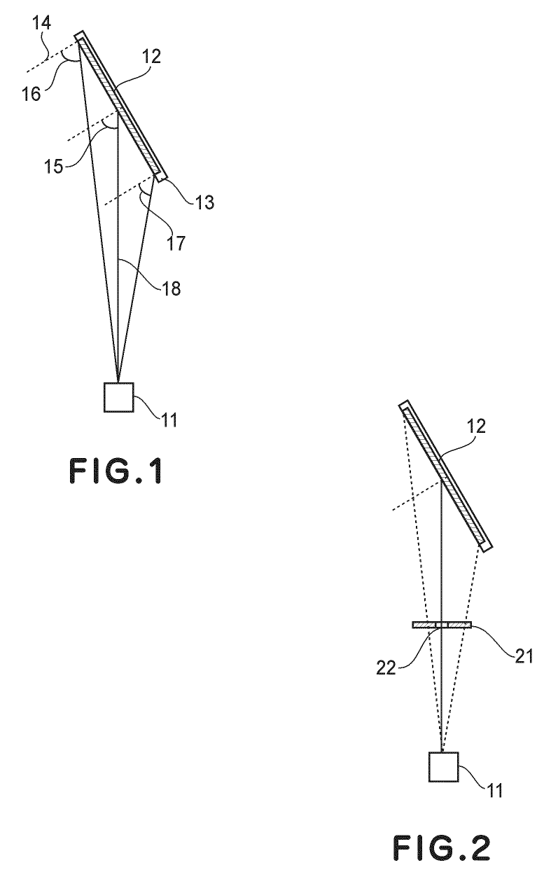

FIG. 1 is a schematic view showing a conventional film forming apparatus using oblique deposition.

Flow of deposition particles emitted from an evaporation source 11 reaches a substrate 12 set at a certain deposition angle to form an oblique deposition film. At that time, deposition angles with respect to a polar angle direction are different at respective points in an in-plane surface of the substrate 2, so that the deposition angle is a deposition angle A represented by a reference numeral 15 at a substrate center, a deposition angle B represented by a reference numeral 16 at a substrate upper end portion, and a deposition angle C represented by a reference numeral 17 at a substrate lower end portion.

In the oblique deposition from a single evaporation source, such a distribution of the deposition angle occurs, so that when a liquid crystal device is prepared by using the substrate, a pretilt angle of liquid crystal varies depending on a position of the substrate. At a position close to the evaporation source, the deposition angle is small and the pretilt angle is low. On the other hand, at a position apart from the evaporation source, the pretilt angle is high.

When a cross-section of the film is observed through an electron microscope, in the film having the small deposition angle and the low pretilt angle, a column is dense. On the other hand, in the film having the large deposition angle and the high pretilt angle, the column is sparse. Thus, a difference in deposition angle leads to a difference in degree of density of the column, thus resulting in a difference in pretilt angle.

Herein, the degree of the column density is defined as a ratio of a volume of the column to a volume of the film, i.e., represents a ratio of a volume of a gap between columns. The degree of the column density can be estimated by taking a refractive index of a film with no gap as a reference (i.e., a film density of 100%) and measuring a degree of lowering in refractive index from the reference (refractive index). The refractive index is measurable by a measuring method such as spectroscopic ellipsometry or the like.

On the substrate surface, at the position apart from the evaporation source and having the large deposition angle, an amount of particles which reach a substrate unit area per unit time is small, so that a film forming speed is slow. At such a position, the pretilt angle is high.

Then, an experiment for directly studying a relationship between the film forming speed and the pretilt angle was conducted.

Under a condition including a fixed deposition angle of 70 degrees and the same film thickness, films were formed at different film forming speeds and the pretilt angle was measured by a crystal rotation method.

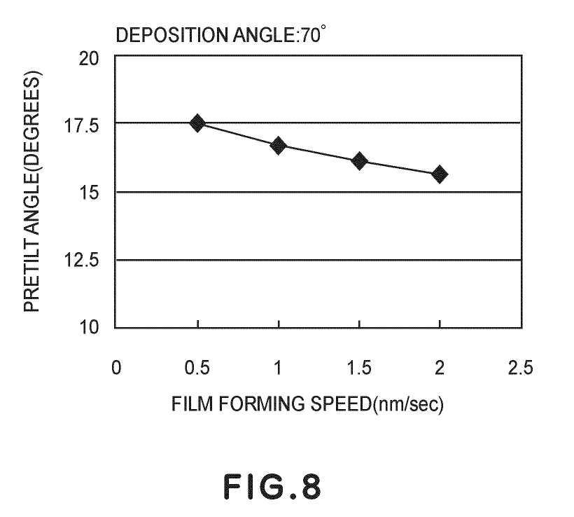

An experimental result is shown in FIG. 8. It is found that the pretilt angle is gradually decreased with an increasing film forming speed even when the oblique deposition is performed at the same deposition angle.

This result can be understood by assumption that the amount of particles reaching the substrate per unit time is increased with an increasing film forming speed and newly formed columns are increased in number rather than extension of individual columns to result in dense columns.

The present invention is based on this result and uniformizes non-uniformity of the pretilt angle due to the difference in deposition angle at an in-plane surface of the substrate. In an area with the large deposition angle, the film forming speed is increased, so that the degree of the column density is increased. On the other hand, in an area with the small deposition angle, the film forming speed is decreases, so that the degree of the column density is decreased. As a result, it is possible to form a film providing a uniform pretilt angle.

In order to increase the film forming speed of the oblique deposition film, a method of increasing a deposition speed by increasing electric power supplied to the evaporation source or a method of controlling the film forming speed by using an openable and closeable shutter or the like disposed between the evaporation source and the substrate may be used.

As a material to be deposited, it is possible to utilize silicon oxide (SiOₓ: x=about 1 to 2) such as silicon dioxide (SiO₂) or silicon monoxide (SiO); magnesium oxide (MgO); aluminum oxide (Al₂O₃); zinc oxide (ZnO); titanium oxide (TiO₂); zirconium oxide (ZrO₂); cobalt oxide (Co₃O₄); iron oxide (Fe₂O₃ or Fe₃O₄); and magnesium fluoride (MgF₂). Particularly, it is desirable that the material is silicon oxide (SiOₓ) such as silicon dioxide (SiO₂) or silicon monoxide (SiO). This is because these materials can easily form a column structure and are relatively easily controlled with respect to the degree of the column density by the above-described energy supplying method.

Next, a method of selecting a film forming area by moving a deposition-preventing member having an opening such as a slit or the like will be described.

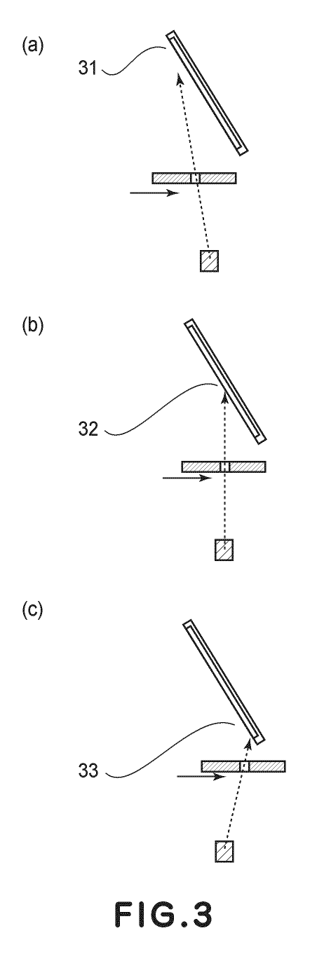

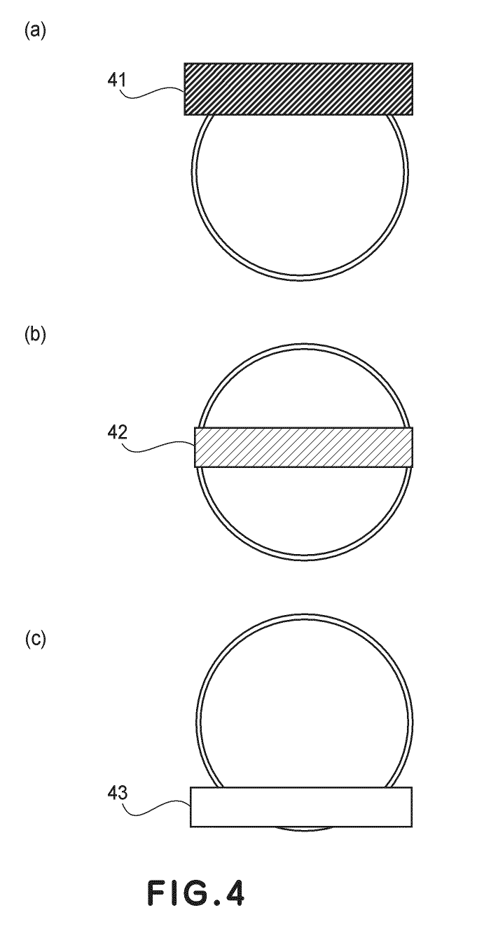

As shown in FIG. 2, a movable deposition-preventing member 21 having a slit 22 is provided between the substrate 12 and the evaporation source 11. Then, the deposition-preventing member 21 is moved in directions as shown in FIGS. 3(a) to 3(c) to select a film forming area. In this case, when the deposition-preventing member 21 is moved to select the film forming area in the order of a film forming area A (31), a film forming area B (32) and a film forming area C (33), a film is formed in an area 41, an area 42 and an area 43, respectively, as shown in FIGS. 4(a) to 4(c). By changing the film forming speed during the film formation in the film forming areas A (31), B (32) and C (33), it is possible to realize the same degree of the column density in the respective areas in the substrate. That is, in the area 41 shown in FIG. 4(a), the degree of the column density is increased by increasing the film forming speed and with the movement of the deposition-preventing member 21 as shown in FIGS. 4(b) and 4(c), the film forming speed is gradually decreased so that the degrees of the column density in the respective areas are equal to each other. Further, in this case, a moving speed of the deposition-preventing member 21 is controlled so that a thickness of an alignment film is equal in the respective areas.

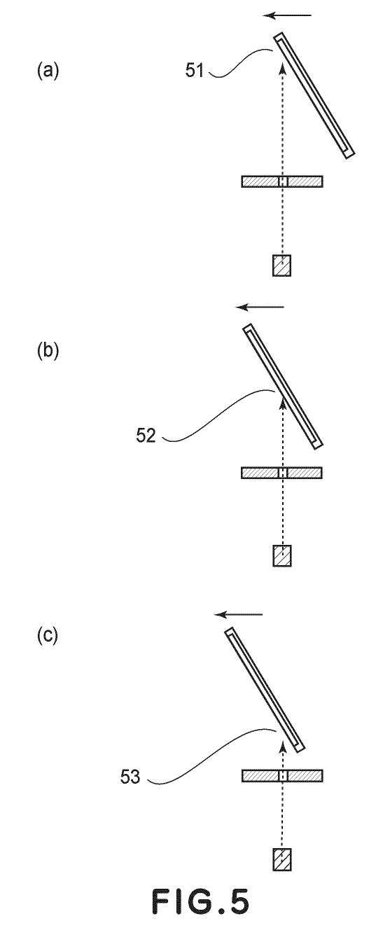

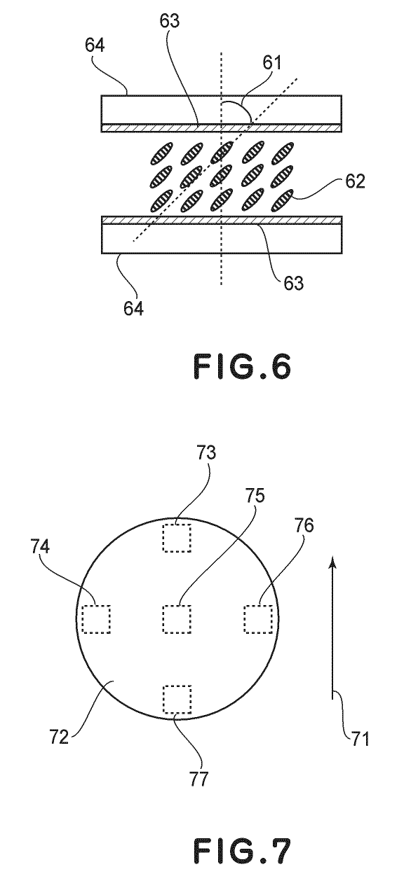

Further, as shown in FIG. 5, it is also possible to select the film forming area depending on the movement of the substrate. In this case, the deposition angles in the respective film forming areas are equal to each other but a difference in film forming speed is caused to occur due to the difference in deposition distance. Particularly, in the case where the evaporation source 11 and the substrate 12 are close to each other, the difference in deposition distance due to the film forming areas is conspicuous. The film forming speed is decreased inversely proportional to the square of the deposition distance, so that an actual film forming speed in the case shown in FIG. 5(a) is decreased compared with the case shown in FIG. 5(c). The difference in film forming speed due to the deposition distance causes a difference in film density, thus leading to an occurrence of the difference in pretilt angle. The difference in film forming speed due to the deposition distance can also be compensated by the film forming method according to the present invention. That is, at the position shown in FIG. 5(a), the film forming speed is set at a higher level and is decreased with movement from the position shown in FIG. 5(a) to the positions shown in FIG. 5(b) and FIG. 5(c), so that the difference in film forming speed due to the deposition distance can be compensated to realize a uniform film forming speed in the respective film forming areas.

### <Film Forming Device of Alignment Film>

An alignment film forming device in the present invention includes a chamber and an exhausting device such as a vacuum pump or the like for exhausting the air from the chamber. In the chamber, an evaporation source, a substrate holding mechanism, a member provided with an opening, and a film forming speed-changing mechanism are provided. The substrate holding mechanism inclines and holds the substrate at an arbitrary angle. The member provided with the opening limits a deposition area of deposition particles onto the substrate and controls the film forming area.

Hereinafter, the respective members (mechanisms) will be described.

The vacuum chamber and the evacuating device are not particularly limited so long as they can control a film forming pressure during the process so as to be kept at an appropriate pressure and may be any chamber and device if they can carry out the alignment film forming method in the present invention.

The substrate holding mechanism is a mechanism for holding the substrate in the vacuum chamber and performing setting of the deposition angle. Further, in some cases, the substrate holding mechanism is moved in the chamber during the deposition and also has a function of selecting the film forming area in the in-plane surface of the substrate by being used in combination with a deposition-preventing member having an opening described later.

The evaporation source is used for vaporizing an evaporation (deposition) source material to cause deposition particles to fly to the substrate and may include those utilizing electron beam (EB) deposition, resistance heating deposition, and the like. The evaporation source material introduced into the evaporation source is not particularly limited so long as the formed alignment film provides appropriate liquid crystal alignment but may preferably include silicon oxide (SiOₓ), particularly silicon dioxide (SiO₂) from the viewpoint of performances required for a liquid crystal display device.

The mechanism for limiting the film forming area on the substrate and selecting the film forming area on the substrate is specifically constituted by the following member and mechanism.

By using a movable deposition-preventing member provided with an opening, it is possible to limit a direction of deposition particles passing through the opening and select the film forming area. It is possible to deposit the deposition particles over the entire surface of the substrate by the movement of the deposition-preventing member. The opening has a rectangular shape so that a long side is perpendicular to the movement direction of the deposition-preventing member and a short side is sufficiently shorter than the long side. As a result, it is possible to accurately control the direction of the deposition particles passing through the opening and thus the deposition angle when the deposition particles reach the substrate.

Further, in the case where the film formation is carried out without moving the deposition-preventing member having the opening, it is possible to limit and select the film forming area by moving the above-described substrate holding mechanism. Also in this case, effective control of the degree of the column density and the film thickness can be performed so long as the opening of the deposition-preventing member has the shape as described above.

The film forming speed-changing mechanism controls an amount of supply of electric power to the evaporation source in synchronism with the movement of the above-described deposition-preventing member or the substrate holding mechanism. It is also possible to control the film forming speed by changing an opened time of the opening of the deposition-preventing member having the opening so as to adjust an amount of a deposition substance passing through the opening. Further, the film forming speed can also be changed by adjusting the moving speed when the opening is moved.

The film forming speed-changing mechanism may preferably be provided with a film thickness monitor using a quartz resonator or the like in the vacuum chamber.

As a control method of the film forming speed, a control method based on the amount of supply of electric power to the evaporation source or the opened/closed time of the shutter may preferably be used since feed-back from the film forming speed monitor can be performed easily.

Hereinbelow, the present invention will be described more specifically with reference to Examples but is not limited thereto.

### EXAMPLE 1

In this example, an inorganic alignment film is formed by carrying out deposition in different film forming areas on a substrate at different film forming speeds and a liquid crystal display device is prepared by using the inorganic alignment film. Specifically, in this embodiment, the deposition is performed at a part of the entire area of the substrate surface at a film forming speed of 2 nm/s and is performed at a remaining part of the entire area of the substrate surface at a film forming speed of 0.5 nm/s, so that a liquid crystal display device having areas different in pretilt angle on one substrate is prepared.

In this embodiment, a silicon wafer and an ITO/glass substrate which have a diameter of 200 mm is used. On the silicon wafer, an aluminum thin film as an electrode and a transistor circuit for driving the liquid crystal display device are formed. In this embodiment, a film (layer) of SiO₂ is formed by electron beam deposition. A distance between an evaporation source and a center of the substrate is set at 100 cm and a deposition angle is set at 70 degrees. A substrate position and the deposition angle are fixed during the deposition.

Next, a deposition mask is disposed on the substrate in order to effect the deposition only in a central area of the substrate.

Next, a power source of the evaporation source is turned on and the film forming speed is set. The film forming speed is monitored by the film thickness monitor and is controllable by feed-back control. The film thickness monitor is disposed at a position in which flow of the deposition particles is not blocked by a slit or the like and always monitors the film forming speed during an operation period of the evaporation source. The film thickness monitor is disposed so that the deposition distance is 100 cm and the deposition angle is 0 degree in addition to the above-described condition.

Then, the film formation is started. In this case, the deposition (oblique deposition) is performed at a deposition angle of 65 degrees and at a film forming speed of 2 nm/s so as to provide a film thickness of 100 nm.

After completion of the film formation, a deposition mask for performing the film formation in an area other than the central area of the substrate, i.e., a portion at which the film formation is not yet performed, is disposed. The deposition is performed at the deposition angle of 65 degrees and at a film forming speed of 0.5 nm/s so as to provide a film thickness of 100 nm.

The substrate prepared by the above-described method is incorporated into a cell, which is subjected to measurement of the pretilt angle. As a result, the pretilt angle at the cell central portion, i.e., the portion at which the deposition is performed at the film forming speed of 2 nm/s is 9.6 degrees. The pretilt angle at the portion other than the cell central portion, i.e., the portion at which the deposition is performed at the film forming speed of 0.5 nm/s is 12.8 degrees.

As described above, by preparing the inorganic alignment film by changing the film forming speed depending on the film forming area, it is possible to create areas providing different pretilt angles in the in plane surface of the same substrate.

### EXAMPLE 2

In this example, an inorganic alignment film is formed by using a movable slit while appropriately changing a film forming speed and a liquid crystal display device is prepared by using the inorganic alignment film.

In this embodiment, a silicon wafer and an ITO/glass substrate which have a diameter of 200 mm is used. On the silicon wafer, an aluminum thin film as an electrode and a transistor circuit for driving the liquid crystal display device are formed. In this embodiment, a film (layer) of SiO₂ is formed by electron beam deposition. A distance between an evaporation source and a center of the substrate is set at 100 cm and a deposition angle is set at 70 degrees. A substrate position and the deposition angle are fixed during the deposition.

Next, a slit for limiting a film forming area is disposed between the substrate and the evaporation source. The slit is moved from an initial position to an end position during film formation. These initial position and end position of the slit are positions in which flow of deposition particles does not reach the substrate. During a period in which the slit moves from the initial position to the end position, the deposition is successively performed in respective areas of the substrate through the slit, thus being finally performed on the entire substrate surface.

Next, a power source of the evaporation source is turned on and the film forming speed is set. The film forming speed is monitored by the film thickness monitor and is controllable by feed-back control. The film thickness monitor is disposed at a position in which flow of the deposition particles is not blocked by a slit or the like and always monitors the film forming speed during an operation period of the evaporation source. The film thickness monitor is disposed so that the deposition distance is 100 cm and the deposition angle is 0 degree in addition to the above-described condition.

After an initial film forming speed is set at 2 nm/s, the movement of the slit is started, thus starting the film formation on the substrate. The slit is moved in a direction in which a film forming area is moved in the order of substrate upper portion, a substrate central portion, and a substrate lower portion. The substrate upper portion refers to an area distant from the evaporation source rather than the substrate central portion when the substrate is disposed in an inclined state, and the substrate lower portion refers to an area opposite from the area for the substrate upper portion.

When the film forming area is the substrate upper portion, the film forming speed monitored by the film thickness monitor is 2 nm/s. The film forming speed is 1 nm/s at the substrate central portion and is 0.5 nm/s at the substrate lower portion. The film forming speed is continuously changed in this way. With respect to the movement of the slit, a moving speed of the slit is controlled so that a deposition film thickness is substantially uniform over the entire substrate surface. Specifically, the moving speed is controlled so as to be higher during the deposition at the substrate upper portion and lower with the movement toward the substrate central portion and then toward the substrate lower portion.

By the above operation, the inorganic alignment film is formed on the Si substrate. In a similar manner, an inorganic alignment film is also formed on a glass substrate provided with an ITO thin film (diameter: 200 mm; size: 8 inches).

On each of the substrates, non-uniformity or the like is not confirmed through optical microscope observation, so that it is possible to confirm that the inorganic alignment film is uniformly formed on each of the substrates.

In order to confirm uniformity of a pretilt angle on the 200 mm-dia. (8-inch) substrate, a liquid crystal cell for pretilt angle measurement is prepared after a deposition thin film is formed in a similar manner on each of two ITO glass substrates. The preparation of the liquid crystal cell for measurement is performed by cutting the two ITO glass substrates from 5 points 73 to 77 shown in FIG. 7 into 5 pairs of substrates and applying each pair of substrates cut from the ITO glass substrates at the same position so that deposition directions of opposing two substrates are anti-parallel to each other. Between the opposing two substrates, a liquid crystal mixture for a vertical alignment (VA) mode (“MLC-6608”, mfd. by Merck Ltd. Japan) is injected to prepare the liquid crystal cells for measurement.

When the pretilt angle is measured at the 5 points 73 to 77 (taken as points A to E, respectively) on the substrate shown in FIG. 7, measured pretilt angles (P.A.) (degrees) are as shown in Table 1 below, so that it is possible to confirm the uniformity of the pretilt angle at each of the points A to E (substrate positions).

TABLE 1

| | Point | | | | |
|---|---|---|---|---|---|
| | A | B | C | D | E |
| P.A. (Degrees) | 15.3 | 15.2 | 15.2 | 15.1 | 15.1 |

Next, liquid crystal display devices for alignment observation are prepared.

An alignment film is formed on each of a 200 mm (8-inch) dia. Si substrate and a 200 mm (8-inch) dia. ITO glass substrate, from which portion for the liquid crystal display devices are cut. These portions are applied to each other with a silica spacer having a particle size of 3 μm so that the inorganic alignment films are disposed in an anti-parallel constitution. Into a gap of these applied portions, the above-described liquid crystal composition is injected to prepare liquid crystal display devices having a cell gap of 3 μm. In a similar manner with different cutting positions, a plurality of liquid crystal display devices are prepared.

A voltage-reflectance characteristics (V-R characteristic) of each of the liquid crystal display devices is similar one, so that it is possible to confirm that each of the liquid crystal display devices provides the same pretilt angle.

A projection type display apparatus is prepared by using each of the liquid crystal display devices prepared above. When an image formed by using the display apparatus is projected onto a screen to observe an image quality, it is possible to effect good display free from display non-uniformity. Further, uniform and good display is obtained even when the liquid crystal display device prepared from any of the substrate positions.

### COMPARATIVE EXAMPLE 1

An inorganic alignment film and a liquid crystal cell are prepared in the same manner as in Example 2 except that the film forming speed is fixed at 1 nm/s.

When the pretilt angle is measured in the same manner as in Example 2, a result (a distribution of the pretilt angle) is shown in Table 2.

TABLE 2

| | Point | | | | |
|---|---|---|---|---|---|
| | A | B | C | D | E |
| P.A. (Degrees) | 16.2 | 15.2 | 15.1 | 15.2 | 14.1 |

When the control of the film forming speed is not performed, non-uniformity of the pretilt angle is caused to occur along the deposition direction in the in-plane substrate of the substrate.

When liquid crystal display devices are prepared in the same manner as in Example 2, V-R characteristics of the liquid crystal display device prepared by using substrates close to the measuring points A (73 in FIG. 7) and E (77 in FIG. 7) are different from each other, so that it is possible to confirm that the difference in pretilt angle adversely affects a display characteristic.

### EXAMPLE 3

In this example, in the case where a deposition-preventing member having a slit is fixed and film formation is performed while moving an inclined substrate, an inorganic alignment film is formed while appropriately changing a film forming speed similarly as in the case of Example 2 and a liquid crystal display device is prepared by using the inorganic alignment film.

The substrate is identical to that used in Example 2. A deposition-preventing member provided with a rectangular-shaped slit is set between a evaporation source and a substrate conveying mechanism. The slit has a long side having a length of 20 cm and a short side having a length of 2 cm. The substrate conveying mechanism is set at an initial position. The substrate conveying mechanism is a mechanism for moving the substrate while keeping the substrate in an inclined state and, in this embodiment, moves the substrate in a direction perpendicular to the long side of the slit as shown in FIGS. 5(a) to 5(c). In this case, a substrate inclination angle is 70 degrees.

Next, the film formation is started by moving the substrate conveying mechanism. The film forming speed is controlled in the same manner as in Example 2 so as to be 1.5 nm/s at the substrate upper portion, 1 nm/s at the substrate central portion, and 0.7 nm/s at the substrate lower portion. The film formation is completed when the substrate mechanism is moved to an end position.

The pretilt angle of the inorganic alignment film prepared by the above-described method is measured in the same manner as in Example 2. At each of the points on the substrate, a relatively uniform pretilt angle is obtained, so that it is found that the pretilt angle is made uniform at each of the substrate points by using the film forming method of this example.

Further, when liquid crystal display devices are prepared in the same manner as in Example 2 and subjected to evaluation of characteristics in the same manner as in Example 2, similar characteristics are confirmed with respect to each of the liquid crystal display devices.

Further, when a projection type display apparatus is prepared by using each of the liquid crystal display devices, it is possible to confirm that characteristics of the liquid crystal display devices prepared from any of substrate positions are uniform and that good display with no display non-uniformity can be effected.

While the invention has been described with reference to the structures disclosed herein, it is not confined to the details set forth and this application is intended to cover such modifications or changes as may come within the purpose of the improvements or the scope of the following claims.

This application claims priority from Japanese Patent Application No. 313901/2007 filed Dec. 4, 2007, which is hereby incorporated by reference.

What is claimed is:

1. A method of forming on a substrate a film of a substance by depositing the substance vaporized from an evaporation source on the substrate in an oblique direction, said method comprising a step of:
changing a deposition rate of the substance depending on a position on the substrate so that the deposition rate of the substance is higher at the position in which the deposition angle is larger.

2. A method according to claim 1, wherein the substance vaporized from the evaporation source is passed through an opening of a member located between the evaporation source and the substrate.

3. A method according to claim 2, wherein a film forming area on the substrate is changed by moving a position of the opening of the member with respect to the substrate.

4. A method according to claim 2, wherein the deposition rate is changed through adjusting a time ratio of opening and closing of the opening.

5. A method according to claim 2, wherein the deposition rate is changed through adjusting the moving speed of the position of the opening of the member with respect to the substrate.

6. A method according to claim 1, wherein the deposition rate is changed through adjusting an evaporation rate of the substance from the evaporation source.
